(19) United States
(12) Patent Application Publication
(10) Pub. No.: US 2023/0077211 A1
(43) Pub. Date: Mar. 9, 2023

(54) INSPECTION METHOD, METHOD FOR MANUFACTURING SEMICONDUCTOR DEVICE, INSPECTION APPARATUS, INSPECTION SYSTEM, AND STORAGE MEDIUM

(71) Applicants: Kabushiki Kaisha Toshiba, Tokyo (JP); Toshiba Electronic Devices & Storage Corporation, Tokyo (JP)

(72) Inventor: Tomoki TAKAYOSHI, Himeji Hyogo (JP)

(21) Appl. No.: 17/677,681

(22) Filed: Feb. 22, 2022

(30) Foreign Application Priority Data
Sep. 7, 2021 (JP) 2021-145651

(51) Int. Cl. H01L 21/66; G01N 21/94; G01N 21/88

(52) U.S. Cl. CPC H01L 22/12; G01N 21/94; G01N 21/8806

(57) ABSTRACT

According to one embodiment, an inspection method includes acquiring a first image based on a reflected light of a first light reflected by a surface of a leadframe when the first light is irradiated on the surface from a first direction. The inspection method further includes detecting a foreign matter at the surface by using the first image. The first direction is tilted with respect to the surface.

### CROSS-REFERENCE TO RELATED APPLICATIONS

This application is based upon and claims the benefit of priority from Japanese Patent Application No. 2021-145651, filed on Sep. 7, 2021; the entire contents of which are incorporated herein by reference.

### FIELD

Embodiments described herein relate generally to an inspection method, a method for manufacturing a semiconductor device, an inspection apparatus, an inspection system, and a storage medium.

### BACKGROUND

It is desirable to increase the accuracy of a leadframe inspection that uses an image.

### BRIEF DESCRIPTION OF THE DRAWINGS

FIG. 1 is a schematic side view illustrating an inspection system according to a first embodiment;

FIG. 2 is a schematic plan view illustrating the leadframe that is the inspection object;

FIG. 3A is a schematic side view for describing an inspection method according to the first embodiment, FIG. 3B is a schematic view showing an image of the portion shown in FIG. 3A;

FIG. 4A is a schematic view showing an image obtained by the inspection method according to the first embodiment, FIG. 4B is a line profile along line A-B of FIG. 4A;

FIG. 5 is a flowchart showing an inspection method according to the first embodiment;

FIG. 6 is a schematic side view showing an inspection method according to the reference example;

FIG. 7A is a schematic side view for describing the inspection method according to the reference example, FIG. 7B is a schematic view showing an image of the portion shown in FIG. 7A,

FIG. 8A is a schematic view showing an image obtained by the inspection method according to the reference example, FIG. 8B is a line profile along line A-B of FIG. 8A;

FIG. 9A is a schematic side view illustrating an inspection system according to a first modification of the first embodiment, FIG. 9B is a schematic plan view illustrating an inspection system according to the first modification of the first embodiment;

FIGS. 10A to 10D are schematic views showing images obtained by the inspection system according to the first modification of the first embodiment;

FIGS. 11A to 11D are schematic views showing images processed by the inspection apparatus according to the first modification of the first embodiment;

FIGS. 12A and 12B are schematic views showing images processed by the inspection apparatus according to the first modification of the first embodiment;

FIG. 13 is a flowchart showing an inspection method according to the first modification of the first embodiment;

FIG. 14 is a schematic view illustrating an inspection region of an image;

FIG. 15 is a schematic view showing an image of a leadframe;

FIG. 16A is a schematic view showing the image processed by the inspection apparatus according to a second modification of the first embodiment, FIG. 16B is a partially enlarged view of FIGS. 16A;

FIG. 17A is a schematic view showing the image processed by the inspection apparatus according to the second modification of the first embodiment, FIG. 17B is a partially enlarged view of FIG. 17A;

FIG. 18 is a flowchart showing an inspection method according to the second modification of the first embodiment;

FIG. 19 is a schematic plan view showing manufacturing processes of a semiconductor device according to a second embodiment;

FIG. 20 is a schematic plan view showing manufacturing processes of the semiconductor device according to the second embodiment;

FIG. 21 is a schematic plan view showing manufacturing processes of the semiconductor device according to the second embodiment;

FIG. 22 is a flowchart showing a method for manufacturing the semiconductor device according to the second embodiment;

and

FIG. 23 is a schematic view showing a hardware configuration.

### DETAILED DESCRIPTION

According to one embodiment, an inspection method includes acquiring a first image based on a reflected light of a first light reflected by a surface of a leadframe when the first light is irradiated on the surface from a first direction. The inspection method further includes detecting a foreign matter at, the surface by using the first image. The first direction is tilted with respect to the surface.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

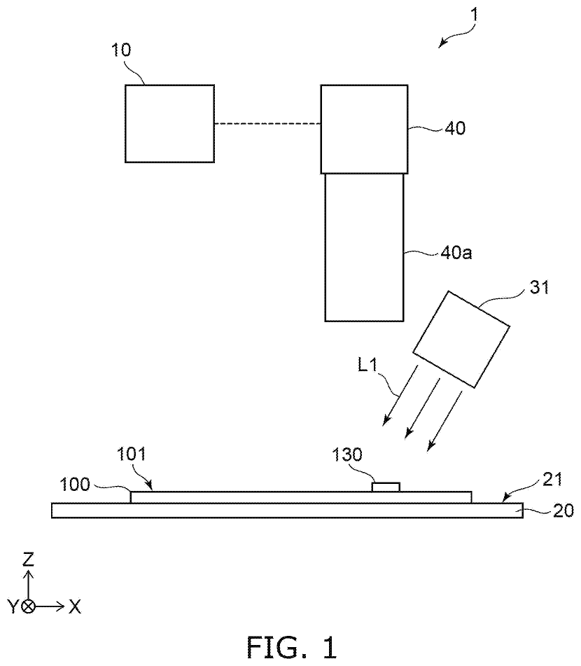

FIG. 1 is a schematic side view illustrating an inspection system according to a first embodiment.

The inspection system 1 shown in FIG. 1 inspects a leadframe 100. The inspection system 1 includes an inspection apparatus 10, a stage 20, a light source 31 (a first light source), an imaging device 40, and an optical system 40a.

The stage 20 holds the leadframe 100. The stage 20 includes a surface 21 that is parallel to the X-Y plane; and the leadframe 100 is placed on the surface 21.

The light source 31 is located higher than the stage 20. The light source 31 irradiates a light L1 (a first light) on the leadframe 100 from a first direction that is tilted with respect to a surface 101. The light source 31 includes a light-emitting device such as a semiconductor light-emitting diode, a fluorescent lamp, etc. As an example, the irradiation angle of the light L1 with respect to the X-Y plane is set to be greater than 60 degrees and less than 90 degrees.

The imaging device 40 is located higher than the stage 20. A portion of the light L1 that is reflected by the surface 101 passes through the optical system 40a and is incident on the imaging device 40. The optical system 40a includes one or more lenses. The imaging device 40 acquires an image (a still image) based on the reflected light of the light L1 that is reflected by the surface 101 by imaging the surface 101 from a position and an angle that are different from those of the light source 31. The imaging device 40 may acquire a video image and may cut out a still image from the video image. The imaging device 40 is a camera that includes a CCD image sensor or a MOS image sensor.

The position and the angle of the imaging device 40 with respect to the stage 20 are set so that a foreign matter of the surface 101 that is described below can be detected. In the example of FIG. 1, the imaging device 40 images the surface 101 from a Z-direction perpendicular to the X-Y plane. The imaging direction of the imaging device 40 may be tilted with respect to the Z-direction as long as the tilt with respect to the X-Y plane of the imaging direction is greater than the tilt with respect to the X-Y plane of the irradiation direction of the light L1.

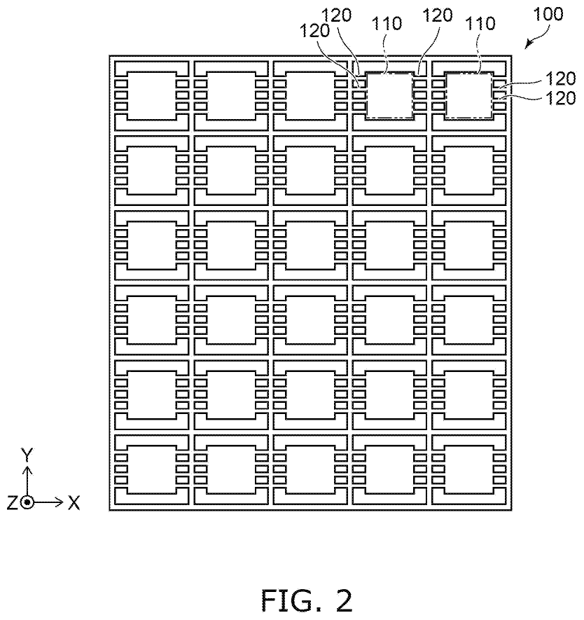

FIG. 2 is a schematic plan view illustrating the leadframe that is the inspection object.

The leadframe 100 is conductive and includes a copper alloy or an iron alloy. As shown in FIG. 2, the leadframe 100 includes multiple die pads 110 and multiple terminal portions 120. The multiple die pads 110 are arranged along an X-direction and a Y-direction. One or more terminal portions 120 are located around each die pad 110. The terminal portions 120 are electrically connected with the die pad 110.

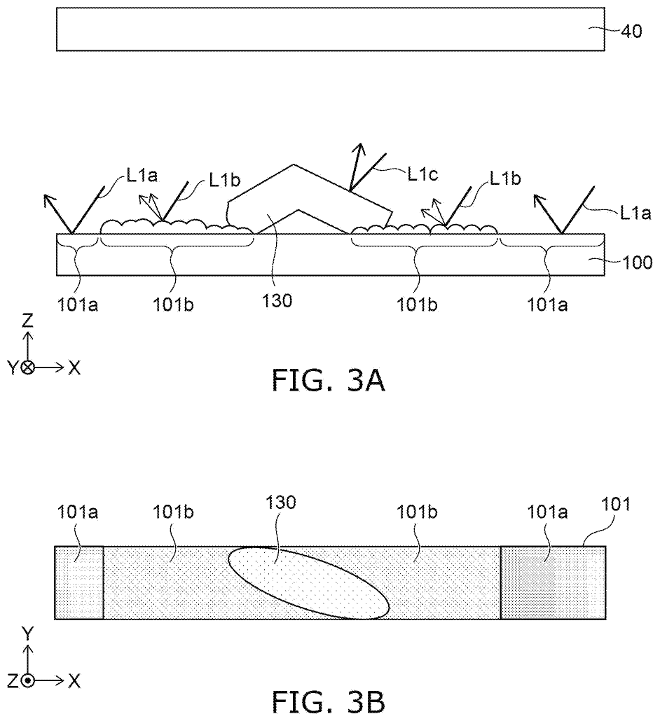

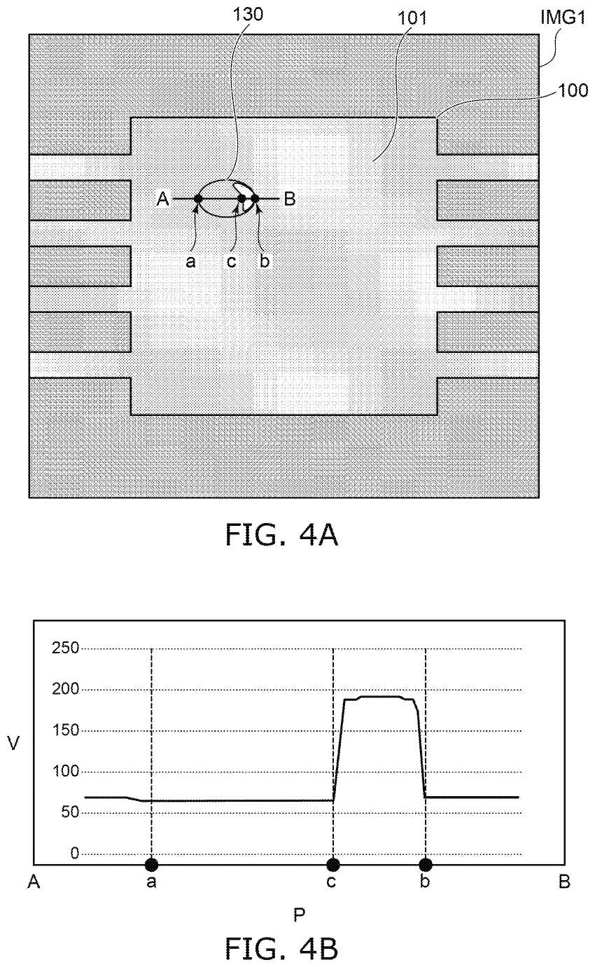

FIG. 3A is a schematic side view for describing an inspection method according to the first embodiment. FIG. 3B is a schematic view showing an image of the portion shown in FIG. 3A. FIG. 4A is a schematic view showing an image obtained by the inspection method according to the first embodiment. FIG. 4B is a line profile along line A-B of FIG. 4A.

FIG. 3A shows an enlarged portion of the surface 101. In the example of FIG. 3A, the surface 101 includes a flat region 101a and a roughened region 101b. The surface roughness of the roughened region 101b is greater than the surface roughness of the flat region 101a. For example, the roughened region 101b is chemically roughened using a chemical liquid. The flat region 101a is planarized by stamping. Although the surface 101 may include regions such as the roughened region 101b that are roughened, the surface 101 as an entirety is substantially parallel to the X-Y plane.

A foreign matter 130 may exist at the surface 101. For example, the foreign matter 130 occurs when a portion of the material that is removed when patterning the leadframe 100 is adhered to the surface 101. Or, the foreign matter 130 is a contaminant or the like that has an origin other than the leadframe 100.

As shown in FIG. 3A, lights L1a to L1c each are irradiated on the flat region 101a, the roughened region 101b, and the foreign matter 130 from the light source 31 from the first direction. The light L1a is specularly reflected by the flat region 101a in a direction that is tilted with respect to the Z-direction. The light Lib is diffusely reflected by the roughened region 101b. Typically, the foreign matter 130 includes a surface that is tilted with respect to the X-Y plane. Therefore, at least a portion of the light L1c is reflected toward the Z-direction by the foreign matter 130.

In the images shown in FIGS. 3B and 4A, a high dot density indicates a low pixel value (luminance). In the graph shown in FIG. 4B, the horizontal axis is a position P in the X-direction, and the vertical axis is a pixel value V. In FIG. 4B, edges of the foreign matter 130 are shown by a point a and a point b. As shown in FIGS. 3B and 4A, an image is obtained in which the pixel values of the flat region 101a, the roughened region 101b, and the foreign matter 130 are different from each other due to the intensity difference between the light reflected by the flat region 101a, the roughened region 1011D, and the foreign matter 130. As shown in FIG. 4B, the pixel value of at least a portion of the foreign matter 130 can be greater than the pixel value of the surface 101. Thereby, at least a portion of the foreign matter 130 can be easily discriminated from the surface 101 in an image IMG1 (the first image) acquired by the imaging device 40.

The inspection apparatus 10 receives the first image acquired by the imaging device 40. The inspection apparatus 10 uses the first image to detect the foreign matter at the surface 101. As one specific example, the inspection apparatus 10 determines a foreign matter region in which the foreign matter is visible in the first image, and compares the surface area of the foreign matter region with a preset threshold. The inspection apparatus 10 determines the existence or absence of the foreign matter 130 at the surface 101 based on the comparison result.

Binarization processing or color extraction is performed to determine the foreign matter region. In binarization processing, the first image is illustrated by two colors (a first color and a second color). The level of the binarization is preset. Due to the binarization processing, at least a portion of the foreign matter 130 is illustrated by white (an example of the first color), and the other regions of the foreign matter 130 are illustrated by black (an example of the second color). The regions that are illustrated using white correspond to the foreign matter region.

In color extraction, pixels of a preset color (another example of the first color) are extracted from the first image. The color of the foreign matter 130 is set as the color to be extracted. The extracted region corresponds to the foreign matter region.

Edge extraction may be performed before the binarization processing. Differential processing of the image is performed in the edge extraction. A binary image in which the edges of the foreign matter 130 illustrated by white is obtained thereby. Subsequently, a binary image is obtained in which hole filling is performed for the region inside the edges by performing dilation processing and erosion processing. The region that is illustrated by white after the hole filling corresponds to the foreign matter region.

The inspection apparatus 10 determines that the foreign matter 130 exists at the surface 101 when the surface area of the foreign matter region is greater than the preset threshold. The inspection apparatus 10 determines that the foreign matter 130 does not exist at the surface 101 when the surface area is not more than the threshold.

Or, the inspection apparatus 10 may compare the first image to a reference image that is prepared beforehand. The inspection apparatus 10 calculates the difference between the first image and the reference image. An image in which the foreign matter 130 does not exist can be used as the reference image. In such a case, the inspection apparatus 10 determines that the foreign matter 130 exists at the surface 101 when the difference is greater than the preset threshold. An image in which the foreign matter 130 exists may be used as the reference image. In such a case, the inspection apparatus 10 determines that the foreign matter 130 exists at the surface 101 when the difference is less than the preset threshold.

The inspection apparatus 10 outputs the determination result. For example, the inspection apparatus 10 stores the determination result and the first image in a memory device. The inspection apparatus 10 may output the determination result and the first image to an output device such as a monitor, etc.

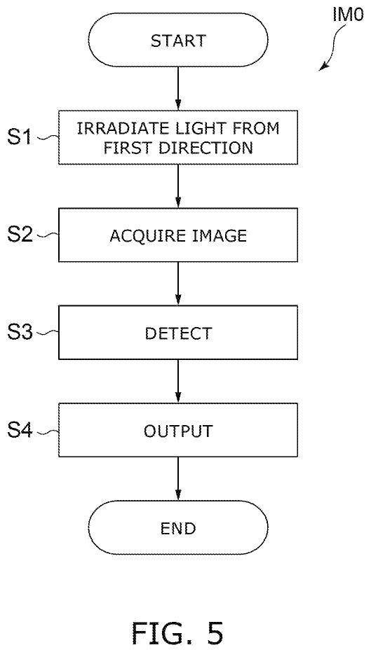

FIG. 5 is a flowchart showing an inspection method according to the first embodiment.

In the inspection method IM0 according to the first embodiment, the light source 31 irradiates the light L1 from the first direction that is tilted with respect to the surface 101 (step S1). The imaging device 40 acquires the first image by imaging the surface 101 on which the light is irradiated (step S2). The inspection apparatus 10 uses the first image to detect the foreign matter (step S3). The inspection apparatus 10 outputs a determination result of whether or not the foreign matter is detected (step S4).

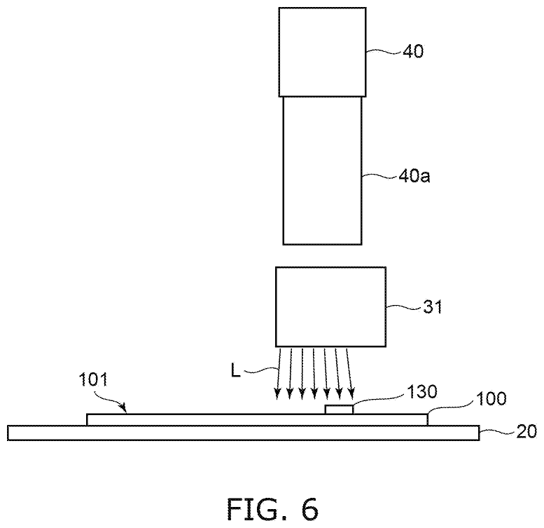

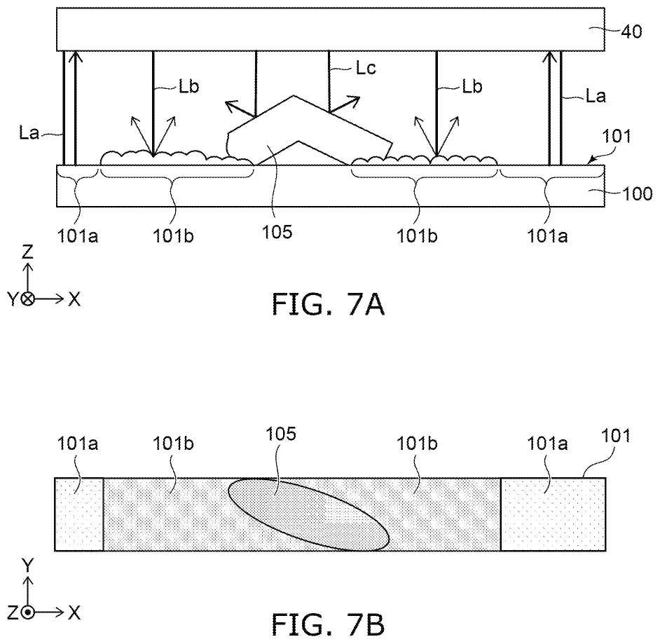

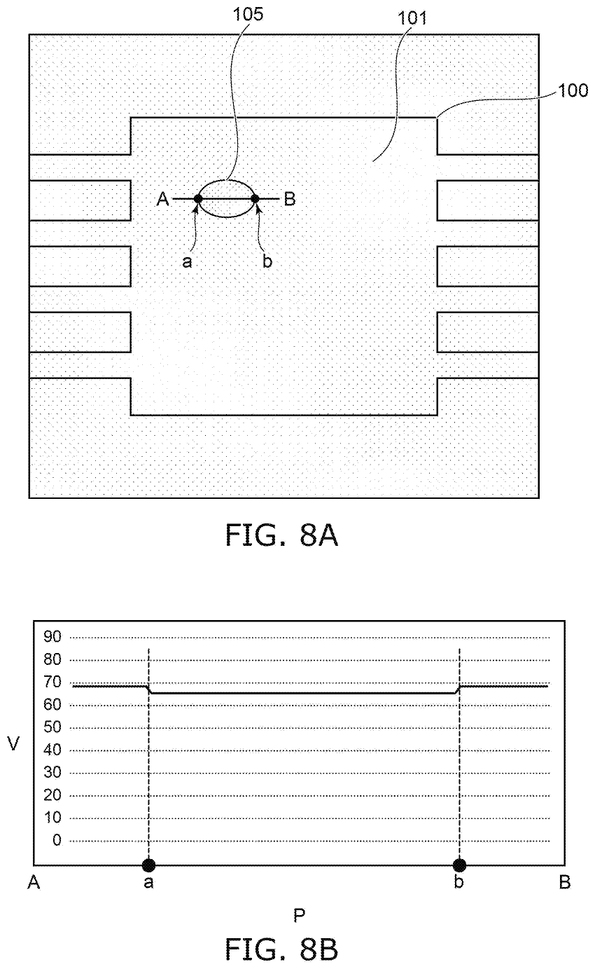

Advantages of the first embodiment will now be described with reference to a reference example. FIG. 6 is a schematic side view showing an inspection method according to the reference example. FIG. 7A is a schematic side view for describing the inspection method according to the reference example. FIG. 7B is a schematic view showing an image of the portion shown in FIG. 7A. FIG. 8A is a schematic view showing an image obtained by the inspection method according to the reference example. FIG. 8B is a line profile along line A-B of FIG. 8A.

In the inspection method according to the reference example shown in FIG. 6, the light source 31 irradiates a light L on the surface 101 along the Z-direction. The imaging device 40 images the surface 101 from the Z-direction.

In the reference example as shown in FIG. 7A, a light La that is incident on the flat region 101a of the surface 101 is specularly reflected toward the Z-direction. A light Lb that is incident on the roughened region 101b and a light Lc that is incident on the foreign matter 130 are reflected in directions that are different from the Z-direction.

In the images shown in FIGS. 7B and 8A, a high dot density indicates a low pixel value (luminance). In the graph shown in FIG. 8B, the horizontal axis is the position P in the X-direction, and the vertical axis is the pixel value V. In FIG. 8B, the edges of the foreign matter 130 are shown by the point a and the point b. In the reference example as shown in FIG. 7B, FIG. 8A, and FIG. 8B, the difference between the pixel value of the foreign matter 130 and the pixel value of the surface 101 (particularly, the roughened region 101b) is low. In particular, when the color of the surface 101 and the color of the foreign matter 130 are of the same type, it is difficult to discriminate the foreign matter 130 from the roughened region 101b as shown in FIGS. 7B and 8A.

Conversely, in the inspection method according to the first embodiment, the light L1 from the light source 31 is irradiated from the first direction that is tilted with respect to the surface 101. An image when the light L1 is irradiated on the leadframe 100 from the first direction is used to detect the foreign matter. Thereby, as shown in FIG. 3B, FIG. 4A, and FIG. 4B, the pixel value difference between the region in which the foreign matter 130 exists and the other regions of the image can be large. For example, compared to the reference example, an image is obtained in which a portion of the contour of the foreign matter 130 is enhanced.

According to the inspection method according to the first embodiment, the foreign matter of the leadframe 100 can be more easily detected from the image; and the inspection accuracy can be increased. The leadframe 100 can be inspected from an image without using an expensive inspection apparatus such as a three-dimensional inspection apparatus, a laser displacement meter, etc.

The imaging device 40 may acquire a color image or a grayscale image. Favorably, the imaging device 40 acquires a color image. The color image that is acquired is arbitrary, e.g., an RGB image, a HSV image, a HSL image, etc. By using a color image in the inspection, the detection of the foreign matter 130 is easy when the color of the foreign matter 130 and the color of the surface 101 are different. According to the inspection method according to the first embodiment, even when the color of the foreign matter 130 and the color of the surface 101 are of the same type, the detection of the foreign matter 130 is easy due to the intensity difference between the reflected light from the surface 101 and the reflected light from the foreign matter 130.

For example, the color of the surface 101 and the color of the foreign matter 130 are of the same type when the material included in the leadframe 100 and the material included in the foreign matter 130 are the same. The foreign matter 130 that has the same type of color may be caused when patterning to remove a portion of the leadframe 100. Laser etching for forming an engraved mark in the leadframe 100 is an example of such patterning. The foreign matter 130 that has the same type of color is caused when a portion of the material is removed by etching and adheres to the surface 101.

### First Modification

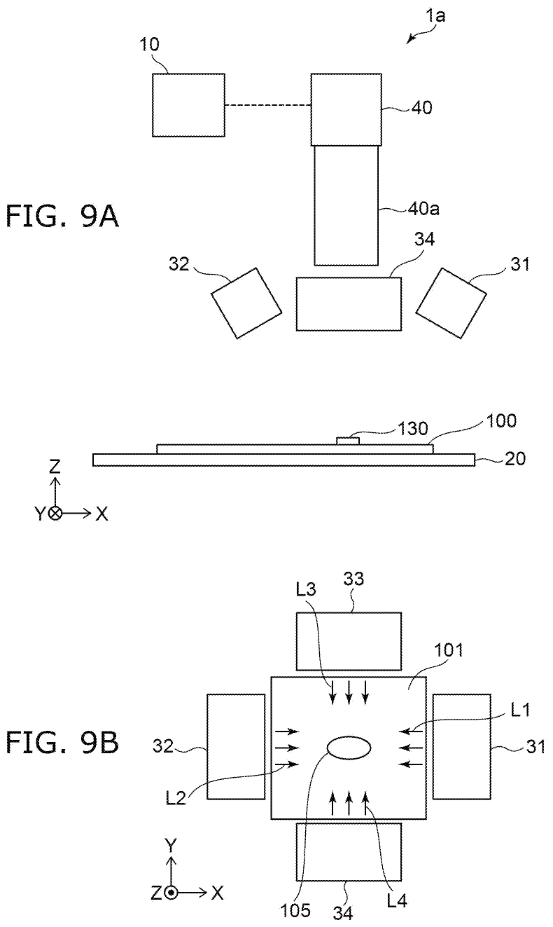

FIG. 9A is a schematic side view illustrating an inspection system according to a first modification of the first embodiment. FIG. 9B is a schematic plan view illustrating an inspection system according to the first modification of the first embodiment.

Compared to the inspection system 1, the inspection system 1a according to the first modification shown in FIGS. 9A and 9B further includes a light source 32 (a second light source), a light source 33 (a third light source), and a light source 34 (a fourth light source).

The light sources 32 to 34 respectively irradiate light L2 (a second light) to L4 from second to fourth directions that are tilted with respect to the surface 101. While one of the light sources is irradiating light, the other light sources do not irradiate light. The first to fourth directions are different from each other. Favorably, as shown in FIG. 9B, the tilt of the first direction with respect to the Z-direction is the opposite orientation of the tilt of the second direction with respect to the Z-direction. The tilt of the third direction with respect to the Z-direction is the opposite orientation of the tilt of the fourth direction with respect to the Z-direction. As an example, the irradiation angles of the lights L1 to L4 with respect to the X-Y plane are set to be greater than 60 degrees and less than 90 degrees.

The light sources 31 to 34 respectively irradiate the lights L1 to L4 on the surface 101 at mutually-different timing. Light is reflected by different surfaces of the foreign matter 130 when the lights L1 to L4 are irradiated. The imaging device 40 images the surface 101 when irradiating each of the lights L1 to L4. Thereby, four types of images are obtained based on the reflected light of each of the lights L1 to L4 that is reflected by the surface 101.

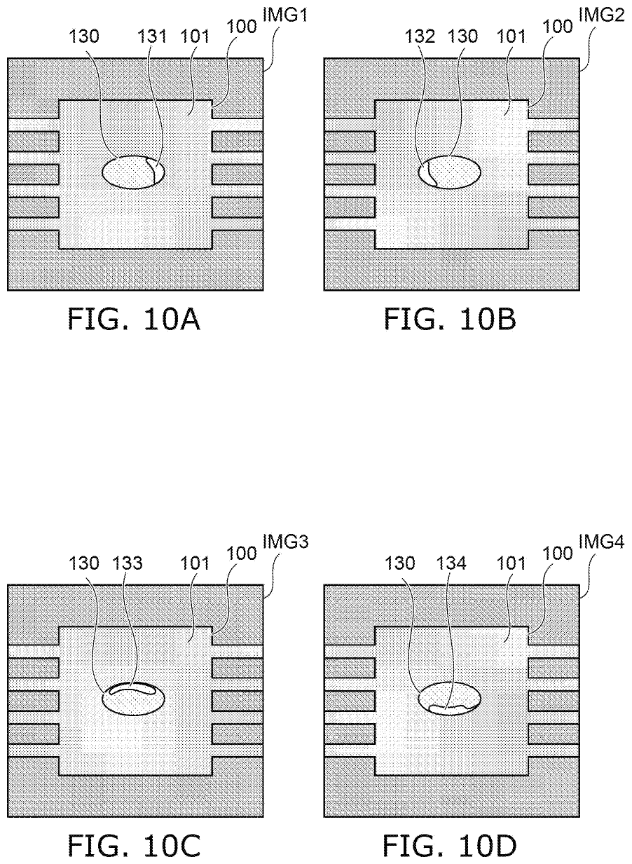

FIGS. 10A to 10D are schematic views showing images obtained by the inspection system according to the first modification of the first embodiment.

FIG. 10A shows the image IMG1 (the first image) of the surface 101 when the light L1 is irradiated from the light source 31. Similarly, FIGS. 10B to 10D show images IMG2 to IMG4 (second to fourth images) of the surface 101 respectively when the lights L2 to L4 are irradiated from the light sources 32 to 34. As shown in FIGS. 10A to 10D, mutually-different portions 131 to 134 of the foreign matter 130 are enhanced according to the direction in which the light is irradiated.

The inspection apparatus 10 uses the multiple images shown in FIGS. 10A to 10D to detect the foreign matter 130 at the surface 101. An example of specific processing is as follows.

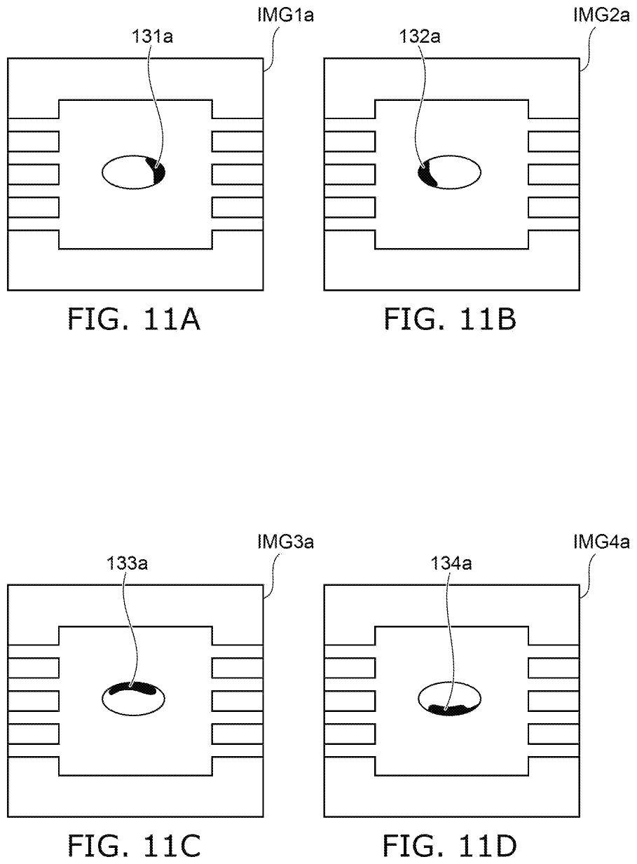

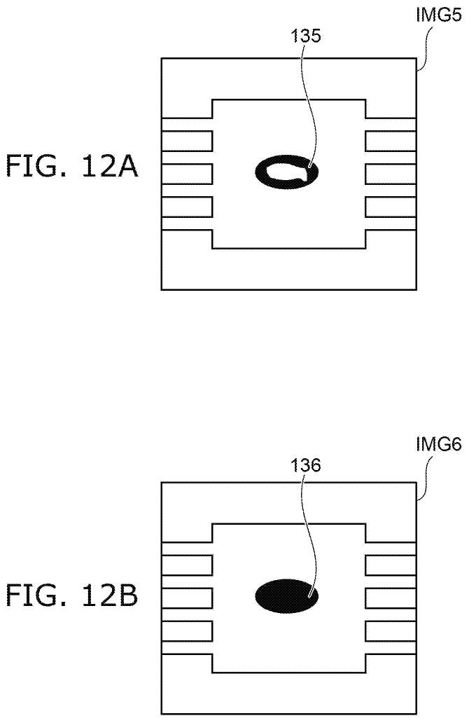

FIGS. 11A to 11D and FIGS. 12A and 12B are schematic views showing processed images.

The inspection apparatus 10 determines foreign matter regions in each image (step S15). For example, the inspection apparatus 10 performs edge extraction, binarization processing, and hole filling for each of the images IMG1 to IMG4. Multiple binary images IMG1a to IMG4a shown in FIGS. 11A to 11D are obtained thereby. In the binary images IMG1a to IMG4a, the portions 131 to 134 are respectively illustrated by black regions 131a to 134a. The black regions 131a to 134a correspond to the foreign matter regions.

The inspection apparatus 10 uses the binary images IMG1a to IMG4a to generate a synthesized image IMG5 shown in FIG. 12A. A foreign matter region 135 in which the black regions 131a to 134a are synthesized exists in the synthesized image IMG5. The foreign matter region 135 corresponds to the union of the black regions 131a to 134a of the binary images IMG1a to IMG4a.

Typically, the pixel values are greater for the end portions of the foreign matter 130 visible in the images IMG1 to IMG4 in the directions in which the lights L1 to L4 are irradiated. Therefore, in the synthesized image IMG5, the foreign matter region 135 is a circular-ring-shaped region in which a hole exists at the center as shown in FIG. 12A. The inspection apparatus 10 obtains a processed image IMG6 shown in FIG. 12B by performing hole filling of the foreign matter region 135 in the synthesized image IMG5. A filled foreign matter region 136 exists in the processed image IMG6.

The inspection apparatus 10 uses the processed image IMG6 to determine the existence or absence of the foreign matter 130 at the surface 101. Specifically, the inspection apparatus 10 compares the surface area of the foreign matter region 136 in the processed image IMG6 with a preset threshold. When the surface area is greater than the threshold, the inspection apparatus 10 determines that the foreign matter 130 exists at the surface 101. When the surface area is not more than the threshold, the inspection apparatus 10 determines that the foreign matter 130 does not exist at the surface 101.

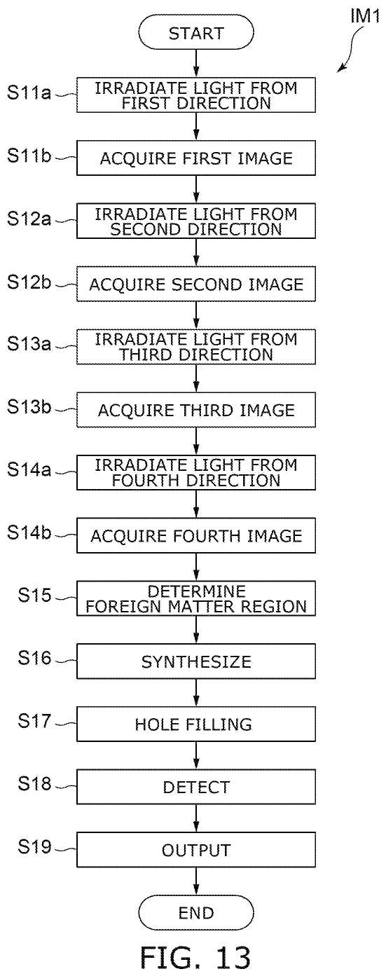

FIG. 13 is a flowchart showing an inspection method according to the first modification of the first embodiment.

In the inspection method IM1 according to the first modification, the light source 31 irradiates the light L1 on the surface 101 from the first direction (step S11a). The imaging device 40 acquires the first image of the surface 101 on which the light L1 is irradiated (step S11b). The light source 32 irradiates the light L2 on the surface 101 from the second direction (step S12a). The imaging device 40 acquires the second image of the surface 101 on which the light L2 is irradiated (step S12b). The light source 33 irradiates the light L3 on the surface 101 from the third direction (step S13a). The imaging device 40 acquires a third image of the surface 101 on which the light L3 is irradiated (step S13b). The light source 34 irradiates the light L4 on the surface 101 from the fourth direction (step S14a). The imaging device 40 acquires the fourth image of the surface 101 on which the light L4 is irradiated (step S14b).

The inspection apparatus 10 determines the foreign matter region in each of the first to fourth images (step S15). The inspection apparatus 10 synthesizes the first to fourth images in which the foreign matter regions are determined (step S16). The inspection apparatus 10 performs hole filling of the foreign matter region of the synthesized image (step S17). The inspection apparatus 10 detects the foreign matter 130 at the surface 101 based on the image after the hole filling (step S18). The inspection apparatus 10 outputs the determination result of whether or not a foreign matter is detected (step S19). The inspection apparatus 10 also may output at least one of the images IMG1 to IMG6. The inspection apparatus 10 also may output the size of the foreign matter 130 calculated from the processed image IMG6.

The execution sequence of the set of steps S11a and S11b, the set of steps S12a and S12b, the set of steps S13a and S13b, and the set of steps S14a and S14b is interchangeable as appropriate.

According to the first modification, the size of the foreign matter 130 can be more accurately calculated by using images of when the light is irradiated from multiple directions. The existence or absence of the foreign matter 130 at the surface 101 can be more accurately determined thereby. The inspection accuracy of the leadframe 100 can be increased.

Four light sources are used in the example described above. The light sources are not limited to the example; the number of light sources used in the first modification is modifiable as appropriate. The number of light sources may be two, three, or more than four. Compared to the inspection method IM0, the inspection accuracy of the leadframe 100 can be increased by using two or more light sources.

### Second Modification

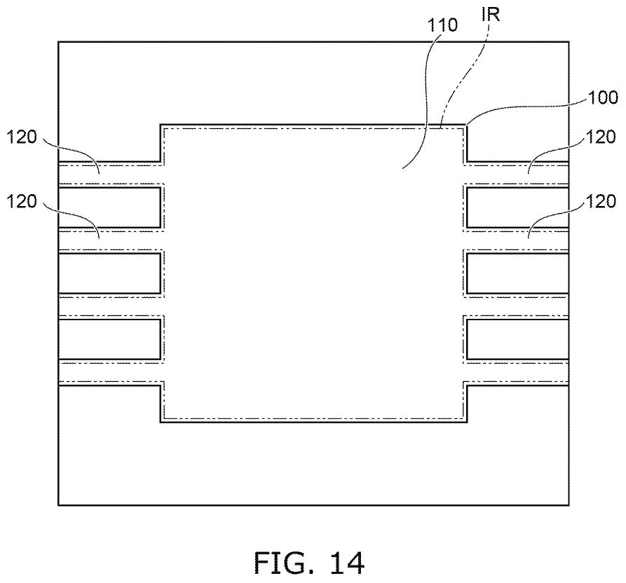

FIG. 14 is a schematic view illustrating an inspection region of an image.

To further increase the inspection accuracy, it is favorable to preset the inspection region in the image. When the inspection region is set, the inspection apparatus 10 detects the foreign matter only from the inspection region of the image. A region in which the foreign matter 130 may exist is set as the inspection region. In the example of FIG. 14, an inspection region IR that includes the die pad 110 and the multiple terminal portions 120 is set. By setting the inspection region, the effects on the inspection of noise, a contaminant on the stage 20 other than the surface 101, etc., can be reduced.

The inspection of the leadframe 100 may be individually performed for one die pad 110 and the terminal portions 120 at the periphery of the one die pad 110, or may be collectively performed for multiple die pads 110 and multiple terminal portions 120. From the perspective of the inspection efficiency, it is favorable to collectively inspect the multiple die pads 110 and the multiple terminal portions 120.

On the other hand, the burden on the user is large when setting the inspection region for the multiple die pads 110 and the multiple terminal portions 120. The inspection region may be automatically set by the inspection apparatus 10 to reduce the burden on the user.

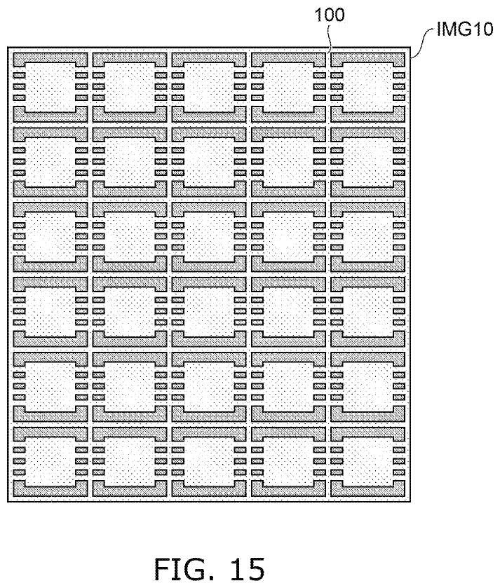

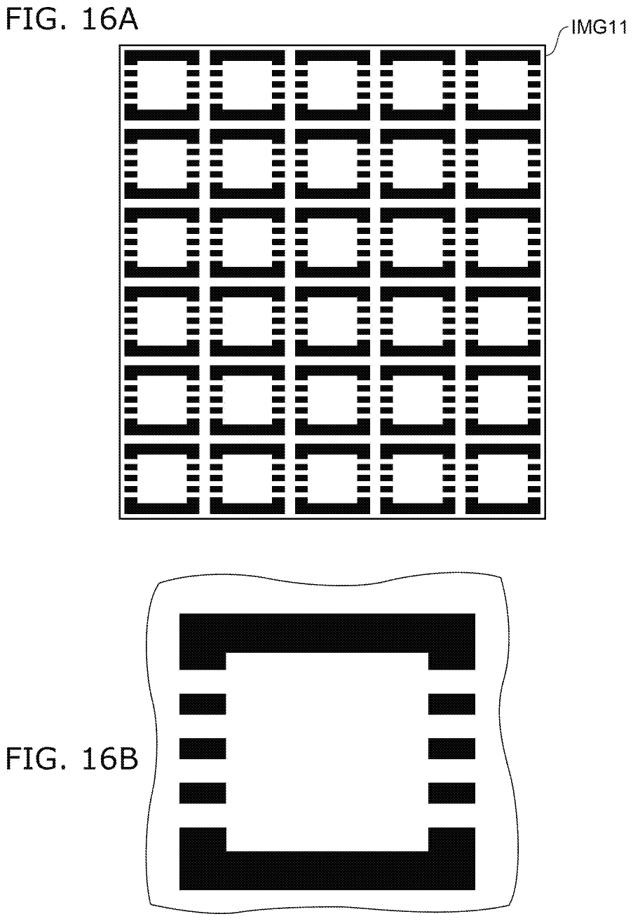

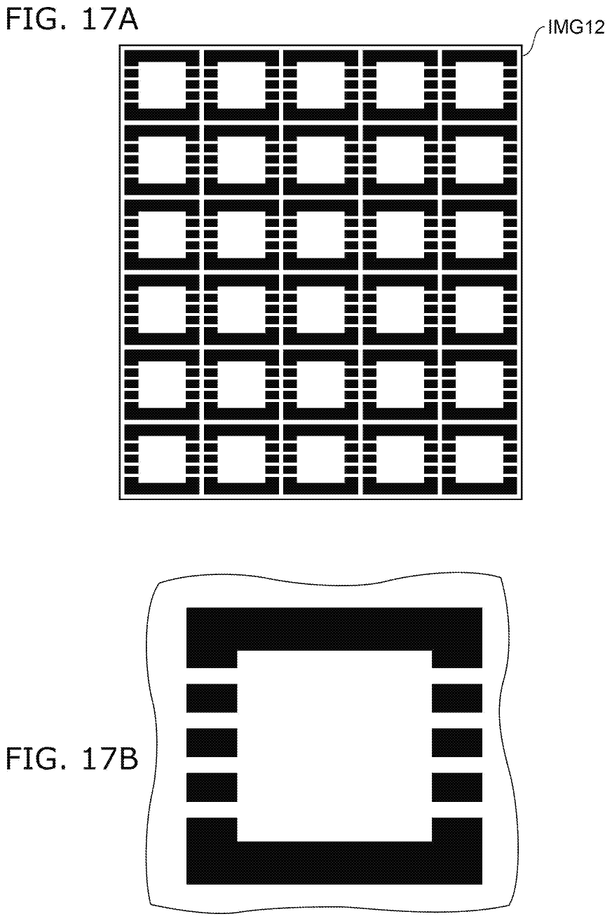

FIG. 15 is a schematic view showing an image of a leadframe. FIGS. 16A and 17A are schematic views showing the image processed by the inspection apparatus according to the second modification of the first embodiment. FIGS. 16B and 17B are partially enlarged views respectively of FIGS. 16A and 17A.

The imaging device 40 acquires an image IMG10 shown in FIG. 15 by imaging the entire leadframe 100 that does not include foreign matter. The inspection apparatus 10 generates a binary image IMG11 shown in FIG. 16A by performing binarization processing of the image. In the example, the leadframe 100 is illustrated using white, and the other regions are illustrated using black.

The inspection apparatus 10 performs erosion processing for the binary image IMG11 shown in FIG. 16A. A binary image IMG12 shown in FIG. 17A is generated by the erosion processing. It can be seen by comparing FIGS. 1613 and 17B that the white regions are made narrower by the erosion processing.

The inspection apparatus 10 sets the white regions in the image shown in FIG. 17A as the inspection region. In the subsequent inspection, the inspection apparatus 10 determines the foreign matter region in the inspection region of each image. Or, the inspection apparatus 10 calculates the difference with the reference image for the pixels in the inspection region.

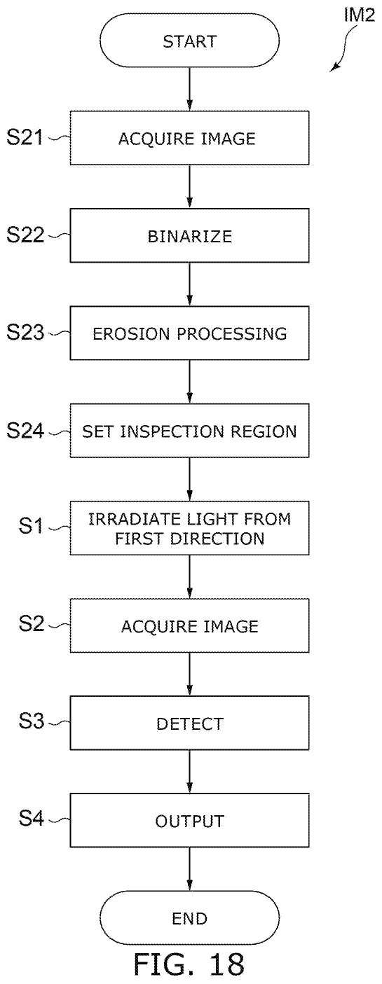

FIG. 18 is a flowchart showing an inspection method according to the second modification of the first embodiment.

In the inspection method IM2 according to the second modification, the imaging device 40 acquires the image of the leadframe 100 (step S21). The inspection apparatus 10 binarizes the image (step S22). The inspection apparatus 10 performs erosion processing of the binary image (step S23). The inspection apparatus 10 uses the binary image after the erosion processing to set the inspection region (step S24). Thereafter, the same steps as the inspection method IM0 are performed. In step S3, the detection of the foreign matter 130 is performed for the set inspection region.

According to the inspection method according to the second modification, the position and the size of the inspection region can be set using the image of the leadframe 100. Therefore, the burden on the user of setting the inspection region can be relaxed. The inspection accuracy can be increased by setting the inspection region for the first image.

### Second Embodiment

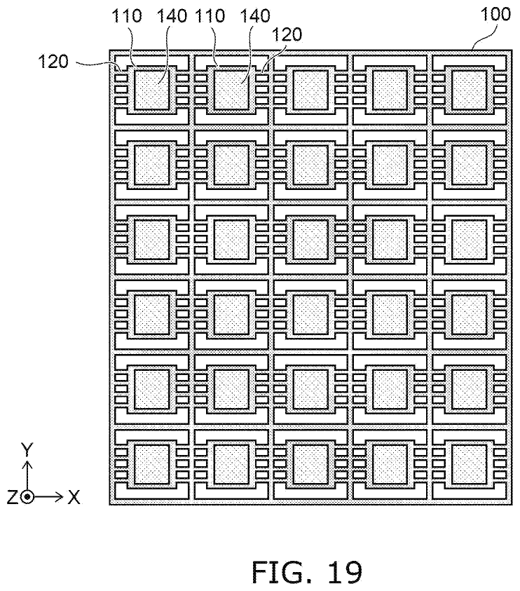

FIGS. 19 to 21 are schematic plan views showing manufacturing processes of a semiconductor device according to a second embodiment.

The leadframes 100 for which foreign matter is not detected are used in the subsequent manufacture of semiconductor devices. The leadframes 100 for which foreign matter is detected are used to manufacture semiconductor devices after removing the foreign matter.

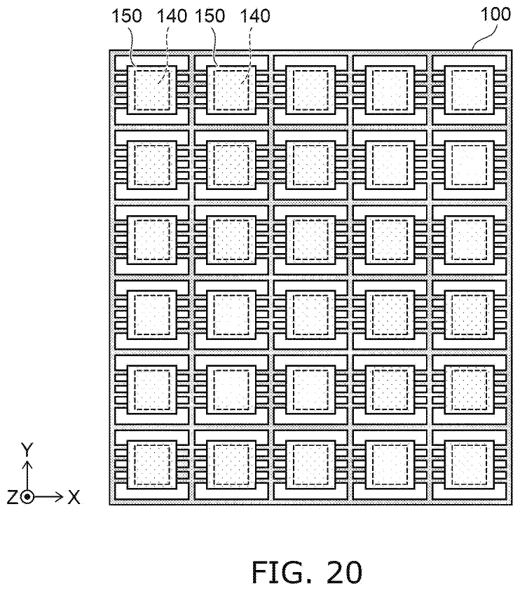

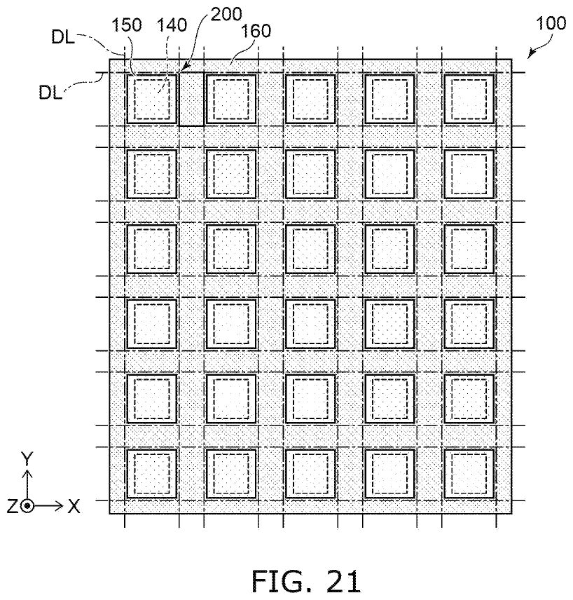

In the manufacture of the semiconductor device as shown in FIG. 19, semiconductor chips 140 are mounted respectively to the die pads 110 of the leadframe 100. The back electrode of the semiconductor chip 140 is electrically connected with the die pad 110. As shown in FIG. 20, lead members 150 are connected on the semiconductor chip 140. Front electrodes of the semiconductor chip 140 are electrically connected with the lead members 150. As shown in FIG. 21, the semiconductor chips 140 are sealed with an insulating member 160. After sealing, the leadframe 100 and the insulating member 160 are diced along a dicing line DL. Singulated semiconductor devices 200 are obtained thereby.

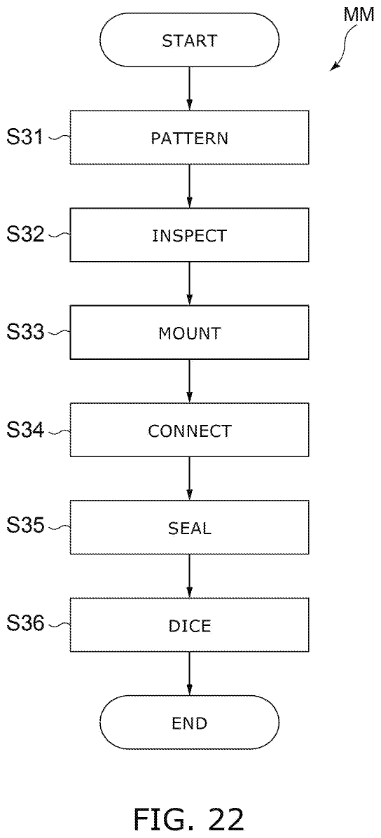

FIG. 22 is a flowchart showing a method for manufacturing the semiconductor device according to the second embodiment.

According to the manufacturing method MM according to the second embodiment, the leadframe 100 is patterned (step S31). In the patterning, the formation of the flat region 101a and the roughened region 101b, the formation of an engraved mark in the leadframe 100, etc., are performed. The leadframe 100 is inspected after the patterning (step S32). In the inspection, one of the inspection methods IM0 to IM2 is performed. After inspecting, the semiconductor chips 140 are mounted to the leadframe 100 (step S33). The lead members 150 are connected on the semiconductor chips 140 (step S34). The semiconductor chips 140 are sealed by the insulating member 160 (step S35). The leadframe 100 and the insulating member 160 are diced (step S36).

The inspection method according to the first embodiment is used in the inspection according to the manufacturing method according to the second embodiment. Therefore, the detection accuracy of the foreign matter can be increased. According to the second embodiment, the likelihood of foreign matter being included in the semiconductor device 200 that is manufactured can be reduced. For example, the reliability of the semiconductor device 200 that is manufactured can be increased.

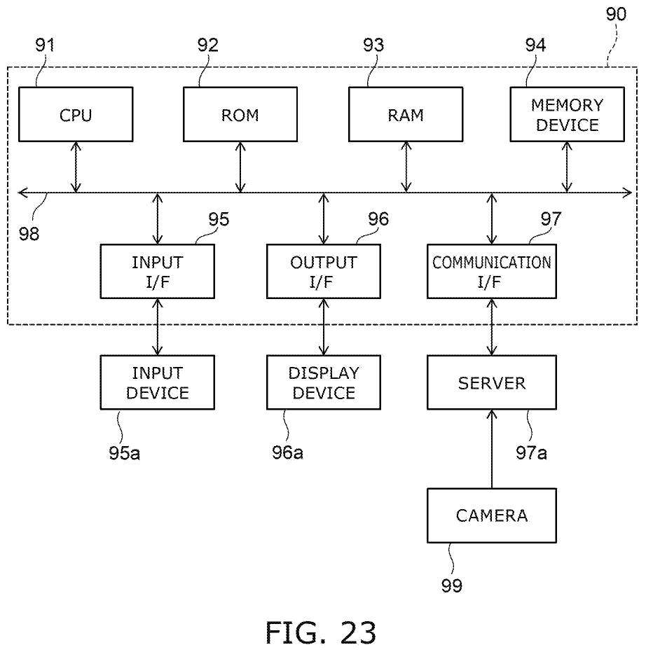

FIG. 23 is a schematic view showing a hardware configuration.

A processing device 90 that includes the hardware configuration shown in FIG. 23 can be used as the inspection apparatus 10. The processing device 90 shown in FIG. 23 includes a CPU 91, ROM 92, RAM 93, a memory device 94, an input interface 95, an output interface 96, and a communication interface 97.

The ROM 92 stores programs that control the operations of a computer. A program that is necessary for causing the computer to realize the processing described above is stored in the ROM 92. The RAM 93 functions as a memory region into which the programs stored in the ROM 92 are loaded.

The CPU 91 includes a processing circuit. The CPU 91 uses the RAM 93 as work memory to execute the programs stored in at least one of the ROM 92 or the memory device 94. When executing the program, the CPU 91 executes various processing by controlling configurations via a system bus 98.

The memory device 94 stores data necessary for executing the programs and data obtained by executing the programs.

The input interface (I/F) 95 connects the processing device 90 and an input device 95a. The input I/F 95 is, for example, a serial bus interface such as USB, etc. The CPU 91 can read various data from the input device 95a via the input I/F 95.

The output interface (I/F) 96 connects the processing device 90 and a display device 96a. The output I/F 96 is, for example, an image output interface such as Digital Visual Interface (DVI), High-Definition Multimedia Interface (HDMI (registered trademark)), etc. The CPU 91 can transmit the data to the display device 96a via the output I/F 96 and can cause the display device 96a to display the image.

The communication interface (I/F) 97 connects the processing device 90 and a server 97a that is outside the processing device 90. The communication I/F 97 is, for example, a network card such as a LAN card, etc. The CPU 91 can read various data from the server 97a via the communication I/F 97. A camera 99 includes a CCD sensor or a CMOS sensor and images the object. The camera 99 stores the image in the server 97a. The camera 99 can be used as the imaging device 40.

The memory device 94 includes not less than one selected from a hard disk drive (HDD) and a solid state drive (SSD). The input device 95a includes not less than one selected from a mouse, a keyboard, a microphone (audio input), and a touchpad. The display device 96a includes not less than one selected from a monitor and a projector. A device such as a touch panel that functions as both the input device 95a and the display device 96a may be used.

The processing of the various data described above may be recorded, as a program that can be executed by a computer, in a magnetic disk (a flexible disk, a hard disk, etc.), an optical disk (CD-ROM, CD-R, CD-RW, DVD-ROM, DVD±R, DVD±RW, etc.), semiconductor memory, or a recording medium (non-transitory computer-readable storage medium) that can be read by another nontemporary computer.

For example, information that is recorded in the recording medium can be read by a computer (or an embedded system). The recording format (the storage format) of the recording medium is arbitrary. For example, the computer reads the program from the recording medium and causes the CPU to execute the instructions recited in the program based on the program. In the computer, the acquisition (or the reading) of the program may be performed via a network.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An inspection method, comprising:
acquiring a first image based on a reflected light of a first light reflected by a surface of a leadframe when the first light is irradiated on the surface from a first direction, the first direction being tilted with respect to the surface; and
detecting a foreign matter at the surface by using the first image.

2. The method according to claim 1, wherein
the foreign matter is detected by comparing a surface area of a foreign matter region determined from the first image to a threshold, or by comparing the first image to a reference image.

3. The method according to claim 1, further comprising:
acquiring a second image based on a reflected light of a second light reflected by the surface when the second light is irradiated on the surface from a second direction,
the second direction being tilted with respect to the surface,
the foreign matter being detected by using the first and second images.

4. The method according to claim 3, wherein
a foreign matter region determined from the first image and a foreign matter region determined from the second image are synthesized, and
the foreign matter is detected using the synthesized image.

5. The method according to claim 4, wherein
a surface area of a foreign matter region in the synthesized image is calculated, and
the foreign matter is detected by comparing the surface area to a threshold.

6. The method according to claim 1, wherein
an inspection region is set for the first image, and
the foreign matter is detected in the inspection region.

7. The method according to claim 6, wherein
a position and a size of the inspection region are set using an image of an other leadframe.

8. The method according to claim 1, wherein
a tilt with respect to the surface of an imaging direction when acquiring the first image is greater than a tilt with respect to the surface of the first direction.

9. The method according to claim 1, wherein
the first image is acquired after patterning the surface and before mounting a semiconductor chip to the surface.

10. A method for manufacturing a semiconductor device, the method comprising:
performing the inspection method according to claim 1; and
mounting a semiconductor chip to the surface for which foreign matter is not detected.

11. An inspection apparatus,
the inspection apparatus acquiring a first image based on a reflected light of a first light reflected by a surface of a leadframe when the first light is irradiated on the surface from a first direction,
the first direction being tilted with respect to the surface,
the inspection apparatus detecting a foreign matter at the surface by using the first image.

12. An inspection system, comprising:
the inspection apparatus according to claim 11;
a first light source irradiating the first light from the first direction; and
an imaging device acquiring the first image by imaging the surface.

13. A storage medium storing a program causing a computer to perform the inspection method according to claim 1.
